(19) United States
(12) Patent Application Publication
(10) Pub. No.: US 2026/0113221 A1
(43) Pub. Date: Apr. 23, 2026

(54) A CONTINUOUS TIME LINEAR EQUALIZER (CTLE) CIRCUIT FOR DYNAMIC PEAKING CONTROL AND METHODS THEREOF

(71) Applicant: Samsung Electronics Co., Ltd., Suwon-si (KR)

(72) Inventors: Manohar SEETHARAM, Bengaluru (IN); A Santosh Kumar REDDY, Bengaluru (IN); Gopinath RAYASAM, Bengaluru (IN); Raghavendra MOLTHATI, Bengaluru (IN); Saikat HAZRA, Bengaluru (IN); Souradip SEN, Bengaluru (IN); Tamal DAS, Bengaluru (IN)

(73) Assignee: Samsung Electronics Co., Ltd., Suwon-si (KR)

(21) Appl. No.: 18/978,611

(22) Filed: Dec. 12, 2024

(30) Foreign Application Priority Data
Oct. 18, 2024 (IN) 202441079454

(51) Int. Cl. H04L 25/03; H04B 1/04

(52) U.S. Cl. CPC H04L 25/03885; H04B 1/0475; H04L 25/03057

(57) ABSTRACT

A continuous time linear equalizer (CTLE) circuit includes one or more tunable switches across differential nodes of one or more load inductors wherein the one or more tunable switches are configured to control inductor peaking, one or more temperature dependent bias voltage blocks connected to the one or more tunable switches, wherein the one or more temperature dependent bias voltage blocks are configured compensate for temperature dependent degradation by controlling gates of the one or more tunable switches, and one or more process variation management blocks connected to the one or more tunable switches, wherein the one or more process variation management blocks is configured to compensate for a process variation.

### CROSS-REFERENCE TO RELATED APPLICATION

This application is based on and claims priority under 35 U.S.C. § 119 to Indian Patent Application number 202441079454, filed on Oct. 18, 2024, in the Indian Intellectual Property Office, the disclosure of which is incorporated by reference herein in its entirety.

### TECHNICAL FIELD

Some example embodiments disclosed herein relate to high speed continuous time linear equalizers, and more particularly to a multi-stage continuous time linear equalizer with a reconfigurable inductor scheme.

### BACKGROUND

Continuous time linear equalizer (CTLE) is a technique used in electronic systems to improve the signal quality in high-speed communication channels. The CTLE circuit is used to counter the channel distortion caused by the low-pass nature of the channel.

### SUMMARY

Some example embodiments herein disclose a continuous time linear equalizer (CTLE) circuit with dynamic peaking control, wherein the CTLE circuit comprises one or more tunable switches across differential nodes of one or more load inductors of the CTLE circuit to control inductor peaking.

Some example embodiments herein disclose a continuous time linear equalizer (CTLE) circuit with dynamic peaking control, wherein the CTLE circuit comprises one or more temperature dependent bias voltage blocks connected to the one or more tuneable switches to control gates of the one or more tuneable switches for compensating temperature dependent degradation.

Some example embodiments herein disclose a continuous time linear equalizer (CTLE) circuit with dynamic peaking control, wherein the CTLE circuit comprises one or more process variation management blocks connected to the one or more tunable switches to compensate process variation.

Some example embodiments herein disclose a method for achieving superior eye performance using a continuous time linear equalizer (CTLE) circuit with dynamic peaking control.

Some example embodiments herein provide a continuous time linear equalizer (CTLE) circuit including one or more tunable switches across differential nodes of one or more load inductors, one or more temperature dependent bias voltage blocks, and one or more process variation management blocks. The one or more tunable switches are connected across differential nodes of one or more load inductors of the CTLE circuit, wherein the one or more tunable switches may be configured to control inductor peaking, one or more temperature dependent bias voltage blocks may be connected to the one or more tunable switches, wherein the one or more temperature dependent bias voltage blocks is configured to control gates of the one or more tunable switches for compensating temperature dependent degradation and one or more process variation management blocks, connected to the one or more tunable switches, wherein the one or more process variation management blocks is configured to compensate for a process variation.

Some example embodiments herein provide a method for achieving superior eye performance using a Continuous time linear equalizer (CTLE) circuit with dynamic peaking control. The method comprises, controlling a programmability feature to extent bandwidth of the CTLE circuit by one or more load of the CTLE circuit, varying the value of frequency peaking by changing effective inductance value of the one or more load inductors by one or more tunable switches, wherein the one or more tunable switches may be placed across the one or more load inductors, controlling the value of effective inductance of the one or more load inductors by the one or more tunable switches across temperatures using a temperature dependent voltage, and controlling the value of effective inductance of the one or more load inductors by the one or more tunable switches across one or more process variation management blocks using a process variation.

These and other example embodiments herein will be better appreciated and understood when considered in conjunction with the following description and the accompanying drawings. It should be understood, however, that the following descriptions, while indicating at least some example embodiments and numerous specific details thereof, are given by way of illustration and not of limitation. Many changes and modifications may be made within the scope of the example embodiments herein without departing from the spirit thereof, and the example embodiments herein include all, or one or more, such modifications.

### BRIEF DESCRIPTION OF FIGURES

Some example embodiments herein are illustrated in the accompanying drawings, throughout which like reference letters indicate corresponding parts in the various figures. Some example embodiments herein will be better understood from the following description with reference to the following illustrative drawings. Some example embodiments herein are illustrated by way of examples in the accompanying drawings, and in which:

FIG. 1 depicts a continuous time linear equalizer (CTLE) circuit stages in wireline receivers rely on inductive peaking, according to conventional art;

FIG. 2 depicts an example waveform depicting continuous time linear equalizer (CTLE) alternate current (AC) response with and without inductor, according to conventional art;

FIG. 3 shows a basic implementation of a peaking gain in continuous time linear equalizer (CTLE) circuit, according to conventional art;

FIG. 4 depicts a continuous time linear equalizer circuit with a switch across the two inductors loading each of the differential arms for a dynamic peaking control, according to some example embodiments as disclosed herein;

FIG. 5A depicts inductive load and switches to control the gate voltage of the switches, according to some example embodiments as disclosed herein;

FIGS. 5B and 5C depict example waveform depicting effective inductance presented to the inductive load and switches, according to some example embodiments as disclosed herein:

FIG. 5D depicts a continuous time linear equalizer (CTLE) circuit stages in a wireline receiver, according to some example embodiments as disclosed herein;

FIGS. 6A, 6B, 6C, and 6D depict example waveform depicting benefits from engaging peaking control, according to some example embodiments as disclosed herein; and

FIG. 7 depicts a method for continuous time linear equalizer circuit with a switch across the two inductors loading each of the differential arms for a dynamic peaking control, according to some example embodiments as disclosed herein.

### DETAILED DESCRIPTION

Some example embodiments herein and the various features and advantageous details thereof are explained more fully with reference to the non-limiting example embodiments that are illustrated in the accompanying drawings and detailed in the following description. Descriptions of well-known components and processing techniques are omitted so as to not unnecessarily obscure example embodiments herein. The examples used herein are intended merely to facilitate an understanding of ways in which example embodiments herein may be practiced and to further enable those of skill in the art to practice some example embodiments herein. Accordingly, the examples should not be construed as limiting the scope of the example embodiments herein.

For the purposes of interpreting this specification, the definitions (as defined herein) will apply and whenever appropriate the terms used in singular will also include the plural and vice versa. It is to be understood that the terminology used herein is for the purposes of describing some particular example embodiments only and is not intended to be limiting. The terms “comprising”, “having” and “including” are to be construed as open-ended terms unless otherwise noted.

The words/phrases “exemplary”, “example”, “illustration”, “in an instance”, “and the like”, “and so on”, “etc.”, “etcetera”, “e.g.,”, “i.e.,” are merely used herein to mean “serving as an example, instance, or illustration.” Some example embodiments or implementation of the present subject matter described herein using the words/phrases “exemplary”, “example”, “illustration”, “in an instance”, “and the like”, “and so on”, “etc.”, “etcetera”, “e.g.,”, “i.e.,” is not necessarily to be construed as preferred or advantageous over some other example embodiments.

Some example embodiments herein may be described and illustrated in terms of blocks which carry out a described function or functions. These blocks, which may be referred to herein as managers, units, modules, hardware components or the like, are physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each, or one or more, block of some example embodiments may be physically separated into two or more interacting and discrete blocks without departing from the scope of the disclosure. Likewise, the blocks of some example embodiments may be physically combined into more complex blocks without departing from the scope of the disclosure.

It should be noted that elements in the drawings are illustrated for the purposes of this description and case of understanding and may not have necessarily been drawn to scale. For example, the flowcharts/sequence diagrams illustrate the method in terms of the steps required, or sufficient, for understanding of aspects of some example embodiments as disclosed herein. Furthermore, in terms of the construction of the device, one or more components of the device may have been represented in the drawings by conventional symbols, and the drawings may show only those specific details that are pertinent to understanding the present example embodiments so as not to obscure the drawings with details that will be readily apparent to those of ordinary skill in the art having the benefit of the description herein. Furthermore, in terms of the system, one or more components/modules which comprise the system may have been represented in the drawings by conventional symbols, and the drawings may show only those specific details that are pertinent to understanding the present example embodiments so as not to obscure the drawings with details that will be readily apparent to those of ordinary skill in the art having the benefit of the description herein.

The accompanying drawings are used to help easily understand various technical features and it should be understood that some example embodiments presented herein are not limited by the accompanying drawings. As such, the inventive concepts should be construed to extend to any modifications, equivalents, and substitutes in addition to those which are particularly set out in the accompanying drawings and the corresponding description. Usage of words such as first, second, third etc., to describe components/elements/steps is for the purposes of this description and should not be construed as sequential ordering/placement/occurrence unless specified otherwise.

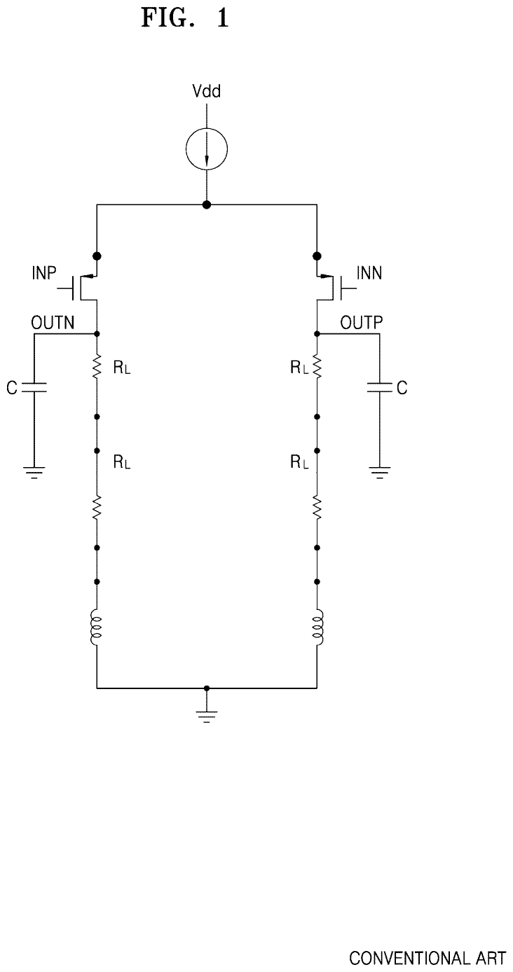

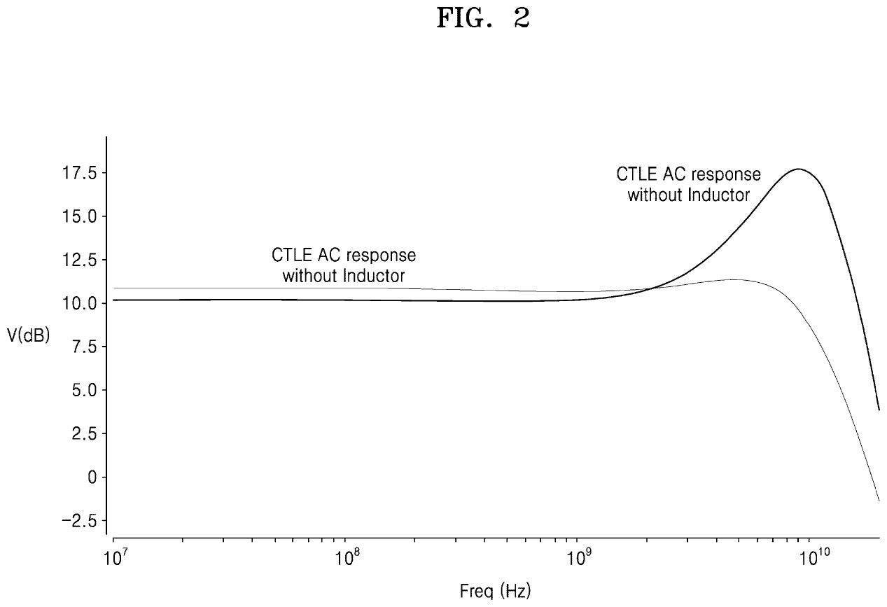

Continuous time linear equalizer (CTLE) is a technique used in electronic systems to improve the signal quality in high-speed communication channels. The CTLE circuit is used to counter the channel distortion caused by the low-pass nature of the channel. FIG. 1 depicts typical CTLE stages of a conventional wireline receiver. The conventional CTLE amplifier stage employs passive and active components in high-speed communication systems to compensate for frequency-dependent losses and distortions in transmission lines, enhancing signal integrity. The CTLE circuit comprises of resistors, capacitors, and inductors. As shown in FIG. 2, the CTLE stages in wireline receivers rely on inductive peaking to extend the bandwidth to enable high speed operation. The CTLE amplifier stage adjusts the amplitude and phase of incoming signals to maintain a flat frequency response, thereby improving the receiver's ability to accurately recover transmitted data. This stage is crucial for mitigating signal degradation and optimizing, or improving, the performance of wireline communication systems, ensuring, or increasing, reliable data transmission over long distances and through challenging environments.

In a CTLE circuit, temperature variations primarily impact the performance due to changes in the transconductance (gm) and drain-source conductance (gds) of the input transistor, as well as variations in the load resistor. The transconductance (gm) is temperature-dependent because it is a function of the carrier mobility and thermal voltage, both of which are influenced by temperature.

Similarly, the drain-source conductance (gds) varies with temperature due to changes in carrier velocity saturation and channel length modulation. Additionally, the resistance of the load resistor can change with temperature, affecting the overall impedance and, consequently, the circuit's frequency response and gain. These variations can lead to shifts in the CTLE's performance, necessitating design considerations to mitigate temperature-induced fluctuations.

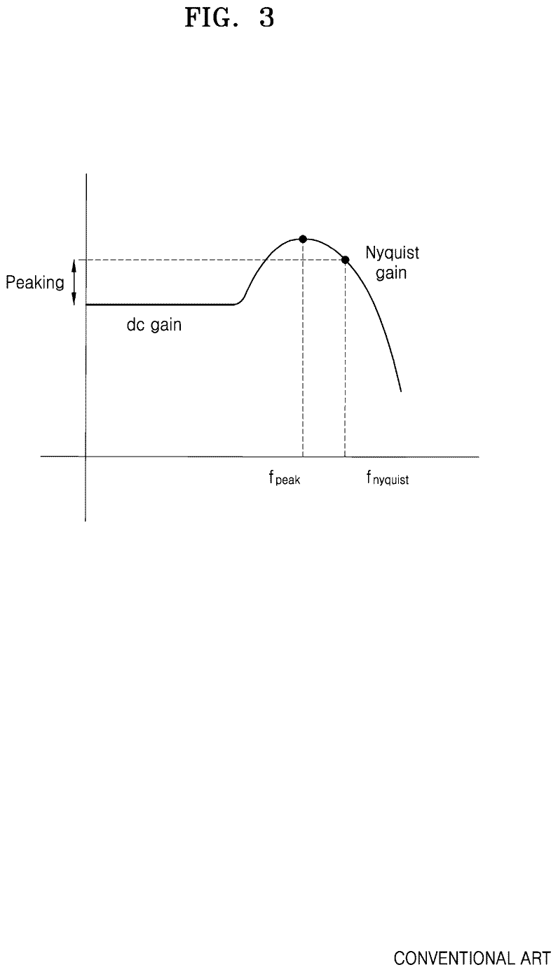

FIG. 3 shows the AC response of the CTLE for high frequency peaking, which results in a degradation in eye performance in the time domain. Nyquist gain variation and peaking variation can be broken down broadly into two categories, for example process variation and temperature variation. Additionally, an overall variation of 12× in Nyquist gain across process, voltage, and temperature (PVT) can be observed, wherein process variation contributes nearly 2× and temperature variation contributes nearly 5×. However, for peaking variation, an overall variation of 2.8× across process, voltage, and temperature (PVT) can be observed, wherein process variation contributes nearly 1.5× and temperature variation contributes nearly 1.8×. The Proportional to Absolute Temperature (PTAT) current biasing can only partially correct for temperature variations because it faces limitations due to output common mode voltage and headroom constraints. PTAT biasing generates a current that varies linearly with temperature, helping to counteract temperature-induced changes in the circuit. However, the effectiveness is limited as the common mode voltage at the output can also vary with temperature, affecting the bias point and overall performance. Additionally, headroom constraints (which refer to the difference between the supply voltage and the sum of the bias voltages) restrict how much the PTAT bias can compensate without pushing the transistors out of their optimal operating regions, thereby limiting its ability to fully correct for temperature variations.

An approach to address the high-frequency problem in the CTLE circuit without disturbing its DC operating point involves introducing a frequency compensation network. This typically involves adding capacitors or inductors in strategic locations within the circuit to counteract high-frequency attenuation. By tailoring the values of these reactive components, the CTLE can boost higher frequencies while maintaining the original DC biasing conditions. This ensures, or increases, that the circuit's low-frequency and DC characteristics remain unchanged, thus preserving its overall operating region and functionality while enhancing its performance at higher frequencies.

In another scenario, an analog equalization circuit performs equalization on the signal, wherein the analog equalization circuit comprises independently tuneable parameters including a peak frequency gain and a mid-range frequency response slope. The analog equalization circuit comprises a first tuneable resistance to tune the peak frequency gain. The study uses a resistor to adjust the peaking performance. In addition to that, the implementation cannot change the performance across temperature.

In another scenario, for programmable peaking gain of a CTLE circuit, the path provides low frequency gain with a bandwidth greater than the Nyquist frequency of the data signal. The CTLE is split into two separate paths, for low frequency and for high frequency to gain better control on peaking. Moreover, there is no mechanism to take care of peaking variation across temperature or process.

Therefore, there is a need in the art for solutions which will overcome the above-mentioned drawback(s), among others.

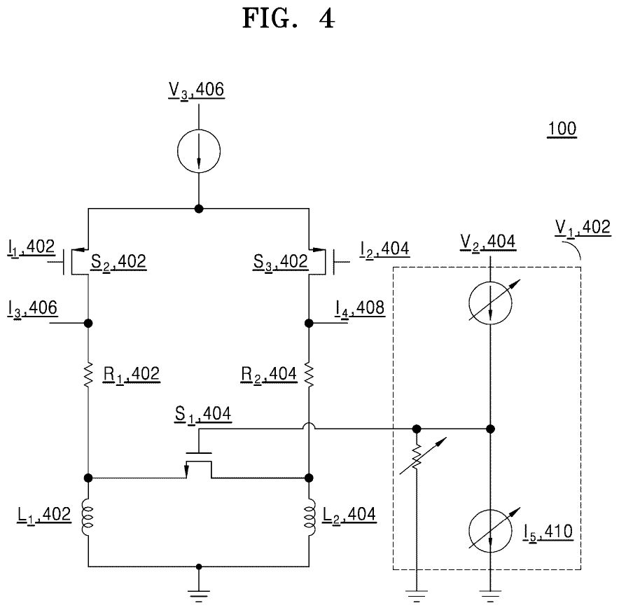

Referring now to the drawings, and more particularly to FIGS. 4 through 7, where similar reference characters denote corresponding features consistently throughout the figures, there are shown some example embodiments.

Some example embodiments herein disclose a continuous time linear equalizer (CTLE) circuit (100) with dynamic peaking control for achieving superior, or increased, eye performance. The CTLE circuit (100) comprises one or more tunable switches across differential nodes of one or more load inductors of the CTLE circuit to control inductor peaking. The tunable switches can be connected to one or more temperature dependent bias voltage blocks to control gates of the one or more tunable switches for compensating temperature dependent degradation. Additionally, the CTLE circuit comprises one or more process variation management blocks that can be connected to the one or more process variation management blocks to compensate for a process variation.

Some example embodiments herein disclose the load inductors configured to extend bandwidth of the CTLE circuit by adding a programmability feature by complex poles and peaking in its alternate current (AC) response.

Some example embodiments herein disclose the tunable switches configured across the differential arms of the load inductors. The tunable switches can vary the frequency peaking by changing load inductance values by one or more stages of the CTLE circuit (100).

Some example embodiments herein disclose controlling the gate voltage of the one or more tunable switches based on temperature, wherein the effective inductance values for the one or more stages of the CTLE circuit can be regulated across temperature variations by a temperature dependent voltage. The effective inductance of the one or more load inductors can be configured to increase temperature, reduce voltage at the gates of the one or more tunable switches, and/or differential current can flow more into the one or more load inductors using a complementary to absolute temperature (CTAT) based biasing.

FIG. 4 depicts a continuous time linear equalizer circuit (100) with a switch across the two inductors loading each of the differential arms for a dynamic peaking control. The CTLE circuit (100) comprises one or more tunable switches, one or more temperature dependent bias voltage blocks, and/or one or more process variation management blocks. The one or more tunable switches (S1 (404)) can be connected across differential nodes of one or more load inductors (L1) of the CTLE circuit (100). The one or more tunable switches (S1 (404)) can control inductor peaking. The one or more temperature dependent bias voltage blocks (V1, 402) can be connected to the one or more tunable switches (S1 (404)). The one or more temperature dependent bias voltage blocks (V1, 402) can control gates of the one or more tunable switches (S1 (404)) for compensating temperature dependent degradation. The CTLE circuit (100) comprises one or more process variation management blocks to compensate for process variation. The CTLE design can use load inductors (L1 (402) and/or L2 (404)) to extend the bandwidth by introducing complex poles and peaking in its AC responses. The bandwidth can be enhanced by a programmability feature, wherein the programmability feature can be provided by the load inductors (L1 (402) and/or L2 (404)). The programmability feature can be controlled to achieve the desired response across temperature. A switch (S1 (404)) can be introduced across the load inductors (L1 (402) and L2 (404)), wherein the switch can load each, or one or more, of the differential arms allowing to change the amount of load inductance seen by the CTLE stages and varying the amount of frequency peaking. The proposed CTLE circuit (100) can comprise a switch (S1, 404) across the load inductors (L1 (402) and (L2 (404)) in each, or one or more, differential arm, wherein the switch (S1 (404)) provides dynamic peaking control. When the switch (S1 (404)) is closed, the load inductors (L1 (402) and/or L2 (404)) are effectively shorted, resulting in reduced peaking gain. Conversely, opening the switch (S1 (404)) increases the peaking effect. This dynamic adjustment allows the CTLE (100) to adapt to varying temperature conditions, optimizing, or improving, signal quality and minimizing, or reducing, distortion. The temperature dependent bias voltage block (V1, 402) may include a first switch (S1 (404)), a second switch (15 (410)), and a variable resistor, one end of the first switch being connected to the second switch. A ground voltage may be applied to one end of the second switch, and a ground voltage may be applied to the variable resistor.

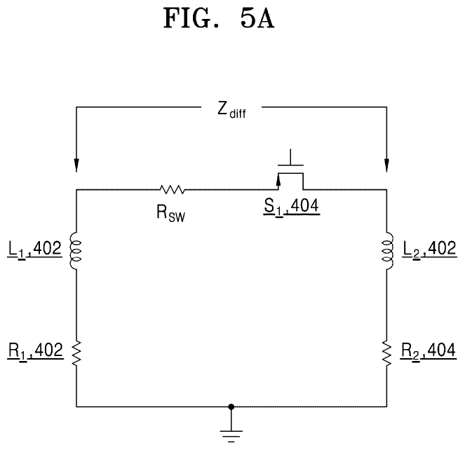

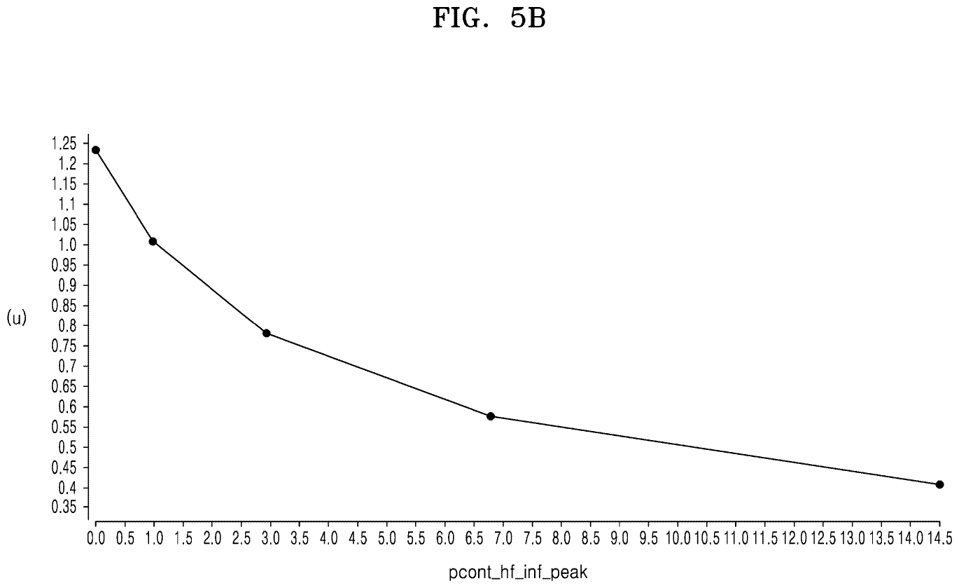

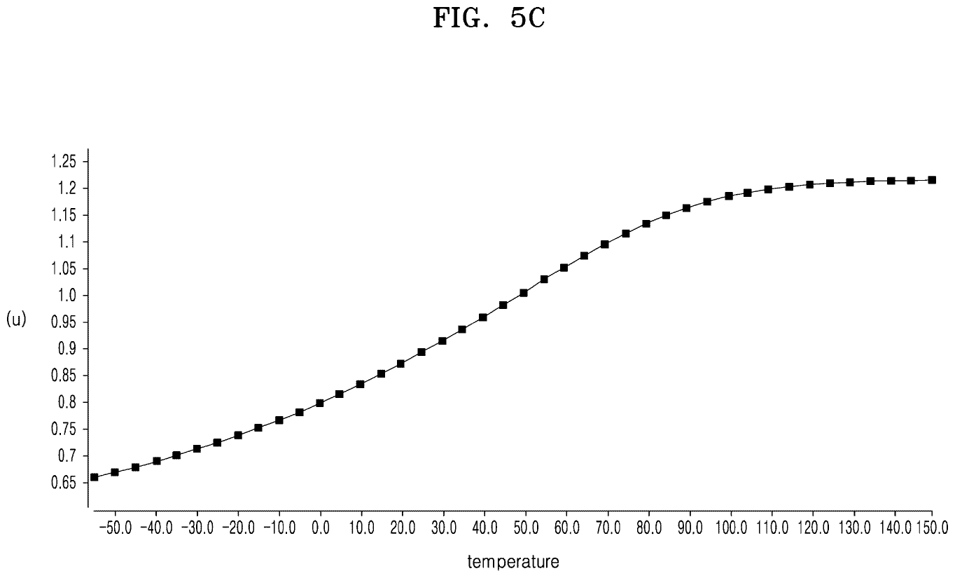

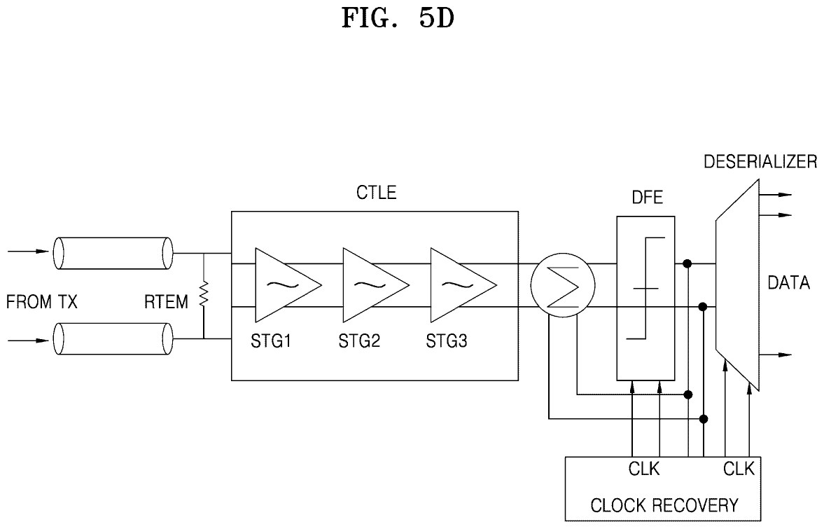

FIG. 5A depicts a continuous time linear equalizer (CTLE) circuit for temperature dependent voltage to control the gate voltage of the switches. The CTLE circuit design can use the load inductors (L₁, 402 and/or L₂, 404) to extend the bandwidth by introducing complex poles and peaking in the AC response. Additionally, process and temperature variation helps with a higher than optimum peaking in cold_cmin corners or a lower Nyquist gain in hot_cmax corners. The switch (S₁ (404)) can be introduced between the two differential passive load inductors (L₁, 402 and L₂, 404) to establish a control point to tweak the effective inductance for determining peaking. The gate bias voltage of the switch (S₁(404)) can be controlled with CTAT current. The CTLE circuit (100) adjusts the gate voltage of its switches based on temperature changes. This adaptation ensures, or enables, the CTLE circuit to maintain optimal, or improved, performance despite temperature fluctuations. The CTLE circuit (100) uses a temperature-sensitive component to generate a voltage that varies with temperature. This voltage then controls the gate voltage of the switches within the CTLE circuit (100), dynamically altering their state to compensate for the effects of temperature variations, thus preserving signal quality and minimizing, or reducing, distortion. The R_{sw} temperature dependent resistor can be associated across the gate voltage, wherein the temperature dependent voltage Z_{diff} used to control the gate voltage along the switches. The temperature dependent voltage Z_{diff} may be calculated according to Equation 1.

$${Z}_{diff} = \frac{2 sL}{[ {( 1 + \frac{2 {R}_{L}}{{R}_{sw}} )}^{2} + {( \frac{2 sL}{{R}_{sw}} )}^{2} ]} \qquad Equation 1$$

The CTLE circuit (100) comprises a temperature-dependent voltage source (V1, 402) to dynamically control the gate voltage of the switches (S₁(404)). The temperature dependent switch resistance (R_{sw}) is controlled by CTAT control of switch gate. As the temperature changes, the voltage level at the gates of the switches (S₁(404)) adjust accordingly. In the CTLE circuit (100), the parasitic resistors (R1(402) and R2(404)) of the respective inductors (L₁, 402 and L₂, 404) can be connected across the gate, enabling the adjustment of the gate voltage in response to temperature changes. The resistance of R_{sw} varies with temperature, thereby modifying the voltage applied to the gates of the switches (S₁(404)) and accordingly, ensuring the switches (S₁ (404)) operate optimally to maintain consistent signal equalization and quality. This temperature compensation ensures, or enables, the CTLE circuit's peaking effect to remain stable across varying environmental conditions. By fine-tuning the switch (S₁(404)) characteristics, the circuit optimizes, or improves, signal equalization and enhances overall system performance. The AC response can remain as close to the desired response by controlling the amount of inductance presented to the CTLE stages across temperature.

FIGS. 5B and 5C depict example waveforms depicting effective inductance presented to continuous time linear equalizer (CTLE), wherein tuning one or more switches across the inductor can reduce the effective inductance presented as load. The division of the differential current between the switch (S₁ (404)) and the inductor (L₁ (402) and/or L₂ (404)) can reduce the effective inductance. The effect of CTAT based biasing on the inductance to the CTLE circuit (100) can result in the voltage at the switch gate reducing and the differential current flowing more into the inductors. The effective inductance of the CTLE circuit (100) can refer to the dynamic behaviour of the inductors (L₁ (402) and/or L₂ (404)) within the circuit. Consequently, the waveform exhibits peaking with enhanced gain at higher frequencies. The graph 5C illustrates the impact of CTAT based biasing on the inductance experienced by the CTLE circuit. As the temperature rises, the CTAT mechanism lowers the voltage at the switch (S₁ (404)) gate. This reduction in gate voltage can cause more differential current to flow into the inductors (L₁ (402) and/or L₂ (404)). Consequently, the effective inductance presented to the CTLE circuit (100) increases dynamically with temperature, optimizing, or improving, the circuit's performance by adapting to varying thermal conditions. This adjustment helps to maintain signal integrity and quality across a range of temperatures. This behaviour ensures, or enables, optimal, or improved, signal equalization and compensates for channel losses.

FIG. 5D depicts continuous time linear equalizer (CTLE) circuit stages in a wireline receiver. The analog equalization in the wireline receivers typically involve a combination of Continuous Time Linear Equalizer (CTLE) stages including stage 1 (STG1), stage 2 (STG2), stage 3 (STG3) and/or a Decision Feedback Equalizer (DFE). The non-linear DFE can boost high frequency content without noise and crosstalk amplification. For example, one or more of stage 1 (STG1) stage 2 (STG2) and/or stage 3 (STG3) shown in FIG. 5D may comprise the CTLE circuit (100) according to example embodiments. The CTLE circuit (100) can “invert” the channel response, providing the inverse of the channel's frequency characteristics. The CTLE circuit (100) can ensure a relatively flat magnitude up to the Nyquist frequency. The CTLE circuit's stages include amplification, zero compensation, and/or shaping of the transfer function. In the overall RX block diagram, the CTLE circuit (100) can precede the DFE, collectively mitigating interference and enhancing signal quality. The DFE can be operatively connected to a deserializer. Additionally, one or more clock recovery blocks are communicatively connected to the DFE block and the deserializer, wherein the deserializer can be connected with the output unit. The CTLE circuit (101) adjusts the signal to counteract channel loss and distortion, while CTAT biasing provides temperature-dependent voltage control to maintain consistent performance. The DFE mitigates inter-symbol interference for accurate data recovery. The SerDes (Serializer/Deserializer) converts data between serial and parallel forms, facilitating high-speed data transfer. Clock recovery extracts the clock signal from the incoming data stream for synchronization, and Termination Resistor (RTERM) matches the receiver's impedance to the transmission line to minimize signal reflections and ensure optimal power transfer. Together, these components enhance signal integrity, minimize, or reduce, errors, and support high-speed communication.

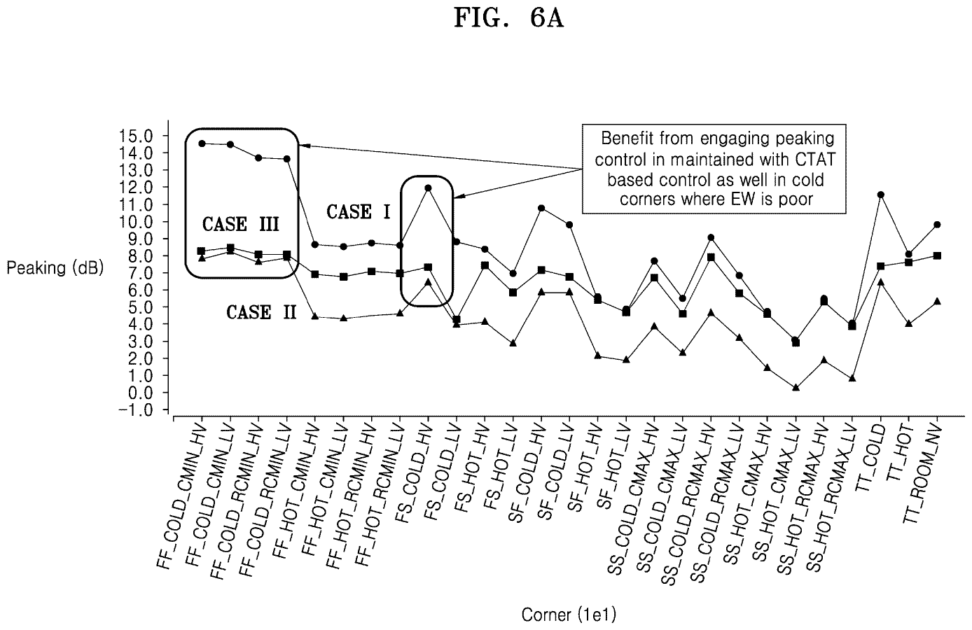

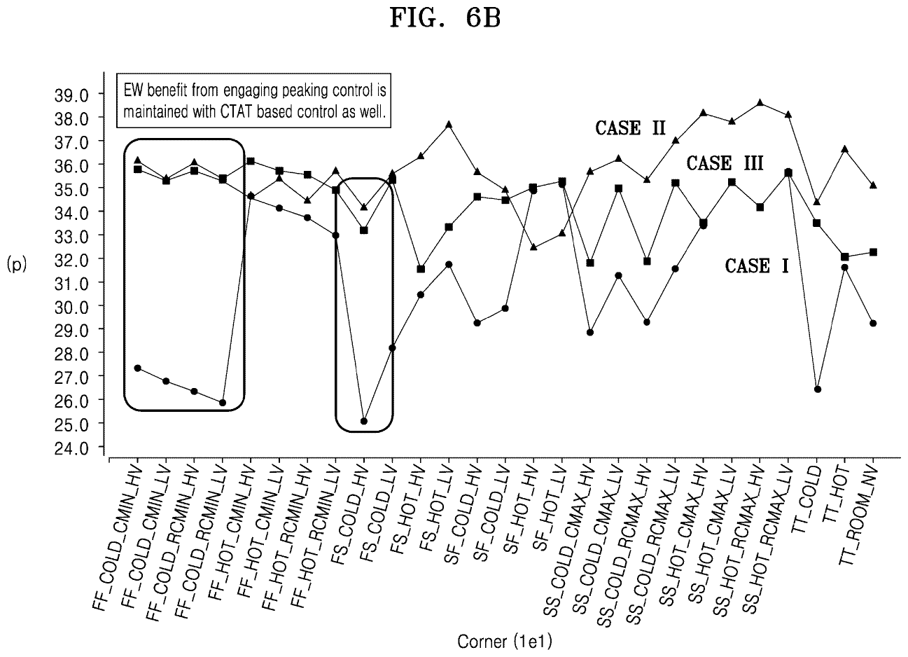

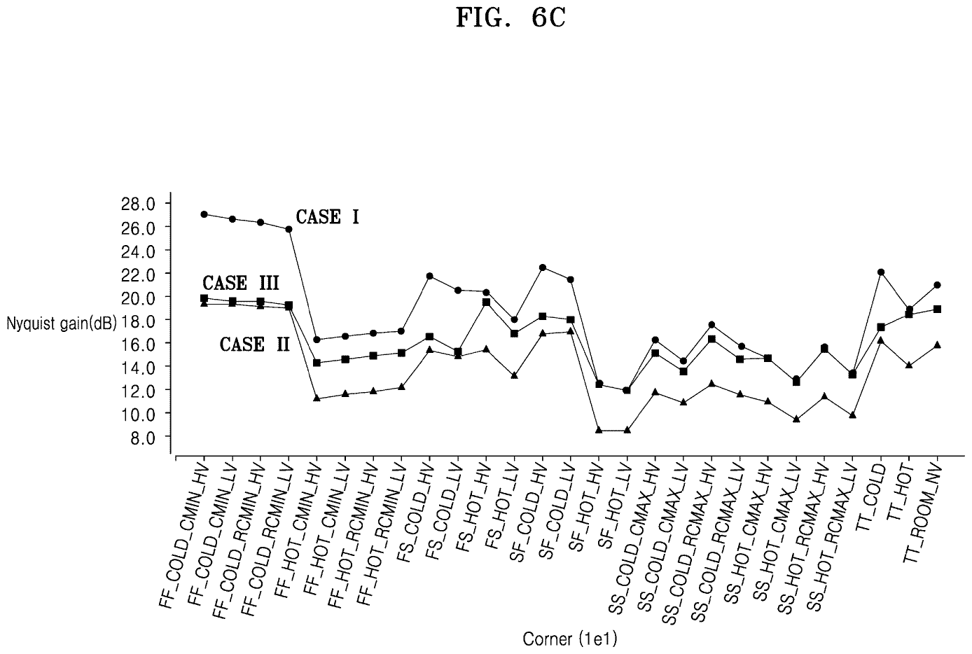

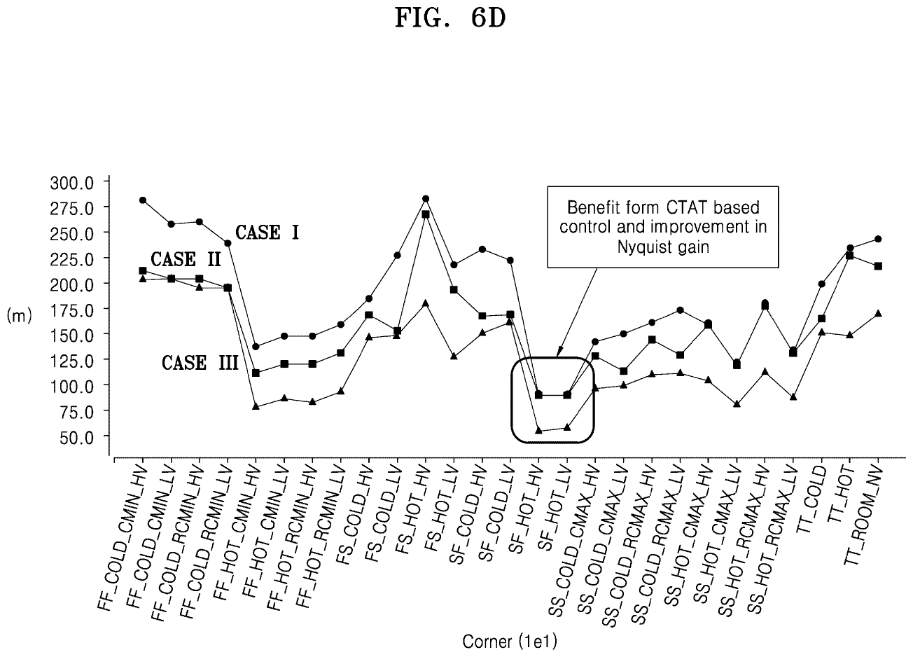

FIGS. 6A, 6B, 6C, and 6D depict example waveforms depicting benefits from engaging peaking control, wherein the cold corners have a higher peaking at default, which leads to poor cyc-width (EW). Peaking control can reduce the maximum peaking value and drop the minimum Nyquist gain. In addition, CTAT based control can reduce the maximum peaking without impacting the minimum Nyquist gain. Moreover, using peaking control without CTAT can reduce the Nyquist gain at hot corners, leading to poor eye-height (EH) and peaking control with CTAT helps to recover the Nyquist gain at hot corners. Furthermore, eye-height can improve with CTAT based control due to improvement in Nyquist gain. The waveforms (as depicted in FIGS. 6A, 6B, 6C, and 6D) illustrate the benefits of peaking control can show that cold corners typically have higher default peaking, which reduces eye-width. Engaging peaking control can lower the maximum peaking value but also decreases the minimum Nyquist gain. However, using CTAT based control can reduce the maximum peaking without affecting the minimum Nyquist gain. Additionally, without CTAT, peaking control can lower the Nyquist gain at hot corners, resulting in poorer eye-height. Peaking control with CTAT can help to recover the Nyquist gain at hot corners, thereby improving eye-height. Consequently, CTAT based control not only manages peaking more effectively but also enhances both EW and EH by maintaining better Nyquist gain across temperature variations.

Some example embodiments herein disclose the simulation cases with respect to tuneable switches. In simulation scenarios involving tunable switches in a CTLE circuit, three cases can be considered: when the tunable switches are on, when the tunable switches are on but without CTAT based control at the switch gate, and when the tunable switches are on with CTAT based control at the switch gate, as depicted in FIGS. 6A, 6B, and 6C presenting case I, II, and III graphs respectively. When the switches are simply turned on, the circuit engages peaking control without any temperature compensation, which can lead to suboptimal performance across different temperatures. When the tunable switches are on but without CTAT control, the CTLE circuit can adjust peaking, but it may still suffer from temperature-related performance issues, such as reduced Nyquist gain at hot corners. However, when the switches are on and CTAT based control is applied at the switch gate, the CTLE circuit dynamically adjusts peaking in response to temperature changes, maintaining optimal Nyquist gain and improving overall signal quality, particularly enhancing eye-height and eye-width across temperature variations.

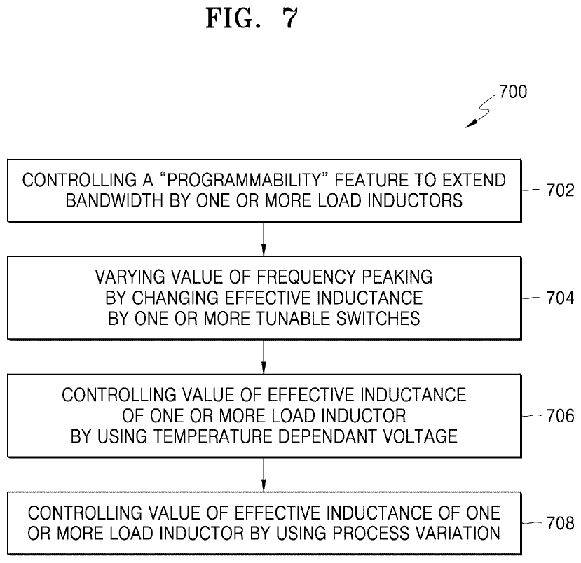

FIG. 7 depicts a method (700) for achieving superior eye performance using a continuous time linear equalizer (CTLE) circuit with dynamic peaking control. In step 702, the one or more load inductors (L₁ 402, L₂ 404) of the CTLE circuit (100) controls a programmability feature to extend bandwidth of the CTLE circuit. In step 704, the one or more tunable switches (S₁ 404) of the CTLE circuit (100) vary the value of frequency peaking by changing inductance value of the one or more load inductors, wherein the one or more tunable switches are placed across the one or more load inductors. In step 706, the one or more tunable switches (S₁ 404) of the CTLE circuit (100) control the value of effective inductance of one or more load inductors (L₁ 402, L₂ 404) across temperatures using a temperature dependent voltage. In step 708, the one or more tunable switches (S₁ 404) of the CTLE circuit (100) control the value of effective inductance of one or more load inductors (L₁ 402, L₂ 404) across one or more process variation management blocks using a process variation. The various actions in method 700 may be performed in the order presented, in a different order or simultaneously. Further, in some example embodiments, some actions listed in FIG. 7 may be omitted.

Some example embodiments disclosed herein can be used to improve the BER and power performance of the receiver and help to improve the AC and transition (TRAN) performance across temperature.

Some example embodiments disclosed herein include a Continuous-Time Linear Equalizer (CTLE) circuit incorporating dynamic peaking control to achieve enhanced eye performance. The CTLE circuit comprises tuneable switches strategically placed across the differential nodes of the load inductors, allowing precise control over inductor peaking. Additionally, it includes a temperature-dependent bias voltage block responsible for regulating the gates of these tuneable switches, effectively compensating for the temperature-induced degradation in eye performance. This combination of adjustable switches and temperature compensation ensures, or allows for, optimal, or increased, performance across varying conditions, without altering the common mode and DC bias points of CTLE, resulting in superior, or increased, signal integrity and reception quality. Additionally, some example embodiments of the proposed CTLE circuit improve eye-width performance of the CTLE by 6 ps (0.15 UI) without any degradation in eye-height.

One or more of the elements disclosed above may include or be implemented in one or more processing circuitries such as hardware including logic circuits; a hardware/software combination such as a processor executing software; or a combination thereof. For example, the processing circuitries more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing description will so fully reveal the general nature of some example embodiments herein that others can, by applying current knowledge, readily modify and/or adapt for various applications such example embodiments without departing from the generic inventive concepts, and, therefore, such adaptations and modifications should and are intended to be comprehended within the meaning and range of equivalents of the example embodiments. It is to be understood that the phraseology or terminology employed herein is for the purpose of description and not of limitation. Therefore, while some example embodiments herein have been described in terms of example embodiments and examples, those skilled in the art will recognize that example embodiments and examples disclosed herein can be practiced with modification within the scope of the example embodiments as described herein.

We claim:

1. A continuous time linear equalizer (CTLE) circuit, comprising:
one or more tunable switches across differential nodes of one or more load inductors, wherein the one or more tunable switches are configured to control inductor peaking;
one or more temperature dependent bias voltage blocks connected to the one or more tunable switches, wherein the one or more temperature dependent bias voltage blocks is configured to compensate for temperature dependent degradation by controlling gates of the one or more tunable switches; and
one or more process variation management blocks connected to the one or more tunable switches, wherein the one or more process variation management blocks is configured to compensate for a process variation.

2. The CTLE circuit as claimed in claim 1, wherein the one or more load inductors is configured to extend bandwidth of the CTLE circuit by adding complex poles and peaking in alternate current (AC) responses of the CTLE circuit.

3. The CTLE circuit as claimed in claim 2, wherein the load inductors are configured to:
extend bandwidth of the CTLE circuit; and
provide a programmability feature by being operatively connected to the one or more tunable switches.

4. The CTLE circuit as claimed in claim 1, wherein the one or more tunable switches is configured to load each of differential arms of the load inductors.

5. The CTLE circuit as claimed in claim 1, wherein the one or more tunable switches is configured to vary an amount of frequency peaking by changing effective load inductance values by one or more stages of the CTLE circuit.

6. The CTLE circuit as claimed in claim 5, wherein a gate of the one or more tunable switches is configured to be controlled by a temperature dependent voltage.

7. The CTLE circuit as claimed in claim 5, wherein the effective load inductance values for the one or more stages of the CTLE circuit are regulated across temperature variations by the temperature dependent voltage and process variation by the process variation management blocks.

8. The CTLE circuit as claimed in claim 1, wherein the one or more load inductors is configured to vary a temperature, reduce voltage at the gates of the one or more tunable switches, and increase a differential current flow into the one or more load inductors based on an effective inductance of the one or more load inductors.

9. A method for increased eye performance using a continuous time linear equalizer (CTLE) circuit with dynamic peaking control, the method comprising:
controlling, by one or more load inductors, a programmability feature to extend bandwidth of the CTLE circuit;
varying, by one or more tunable switches, a value of frequency peaking by changing an effective inductance value of the one or more load inductors, wherein the one or more tunable switches is connected across the one or more load inductors;
controlling, by the one or more tunable switches (S₁ 404), value of effective inductance of the one or more load inductors (L₁ 402, L₂ 404) across temperatures using a temperature dependent voltage; and
controlling (708), by the one or more tunable switches (S₁ 404), value of effective inductance of the one or more load inductors (L₁ 402, L₂ 404) across one or more process variation management blocks using a process variation.

10. The method (700), as claimed in claim 9,
loading, by the one or more tunable switches, each of a differential arm of the one or more load inductors.
